(19) United States
(12) Patent Application Publication
(10) Pub. No.: US 2006/0115673 A1
(43) Pub. Date: Jun. 1, 2006

(54) Organic light emitting device with improved electrode structure

(75) Inventor: Shi-Hao Li, Banciao City (TW)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: AU Optronics Corporation

(21) Appl. No.: 11/001,892

(22) Filed: Dec. 1, 2004

(51) Int. Cl. H01L 51/54; H05B 33/12

(52) U.S. Cl. 428/690; 428/917; 313/504; 313/506

(57) ABSTRACT

An organic light-emitting device comprising an anode, a hole injection layer, a hole transport layer and an organic emitting layer. An electron source is disposed over the organic emitting layer. The electron source comprises a cathode made from a noble metal such as Ag; a buffer layer made from Alq₃ doped with alkali fluoride or alkaline earth fluoride such as CsF; and an electron transport layer made from Alq₃. Additionally, a layer of CuPc is provided between the buffer layer and the electron transport layer. Alternatively, the electron source comprises a cathode made from a noble metal and an electron transport layer made from Alq₃:CsF/CuPc disposed between the cathode and the organic emitting layer.

### FIELD OF THE INVENTION

The present invention relates generally to a light emitting device and, more particularly, to organic light emitting diodes.

### BACKGROUND OF THE INVENTION

Organic light emitting diodes (OLEDs) are known in the art. As shown in FIG. 1, a typical OLED 10 comprises a substrate 12, an anode layer 14, a hole transport layer (HTL) 16, an emissive layer (EML) 18, an electron transport layer (ETL) 20 and a cathode layer 22. In addition, a hole injection layer (HIL) 15 is disposed between the anode layer and the HTL. Furthermore, a buffer structure 21 may be disposed between the ETL and the anode.

Raychaudhuri et al. (U.S. Pat. No. 6,579,629 B1) discloses an OLED wherein the anode is made from ITO; the HIL is made from a fluorinated polymer CFₓ, where x is 1 or 2; the HTL is made from 4,4′-Bis[N-(1-naphthyl)-N-phenylamino]biphenyl (NPB); the EML is made from Alq₃:C545T, with Alq₃ being Tris(8-hydroxyquinoline) aluminum and C545T being 1H,5H,1H-[1]Benzopyrano[6,7,8-ij]quinolizin-11-one, 10-(2-benzothiazolyl)-2,3,6,7-tetrahydro-1,1,7,7-tetramethyl-(9CI); the ETL is made from Alq₃, the buffer structure comprises a first buffer layer made from LiF and a second buffer layer made from copper-phthalocyanine (CuPc); and the cathode is made from Al:Li (3 w %).

Lee et al. (U.S. Patent Application 20040157084) discloses an OLED wherein the HIL is made from IDE406 (manufactured by IDEMITSU CORPORATION), the cathode layer is made of Al; the ETL layer is made from Alq₃; and a thin layer of LiF is vacuum deposited between the cathode layer and the ETL layer.

Hung et al. (U.S. Pat. No. 5,776,623) discloses an eletroluminescent device wherein the HIL is a 15 nm-thick copper-phthalocyanine (CuPc) layer; the HTL is a 60 nm-thick NPB layer; the ETL is a 75 nm-thick 8-tris-hydroxyquinoline aluminum (Alq₃) layer. The buffer layer is a 0.5 nm-thick lithium fluoride (LiF) layer. The lithium fluoride layer can be replaced by magnesium fluoride (MgF₂), calcium fluoride (CaF₂), lithium oxide (Li₂O) or magnesium oxide (MgO). The cathode layer can be made from aluminum and MgAg. Ag and Au are also used in the cathode layer.

An example of prior art OLED is shown in FIG. 2.

In fabricating blue OLEDs, it is imperative to provide an effective cathode for electron injection. In order to increase the electron injection efficiency, a cathode is usually made from a material that has a low work function so as to reduce the energy barrier between the cathode and the ETL. For example, with an Alq₃ electron transport layer (LUMO=2.9 eV), certain materials such as Ca (2.9 eV) and Mg (3.6 eV) seem to be good candidates for the cathode layer. However, Ca and Mg are known to be problematic in storage and in the fabricating process. Alternatively, when Al is used as cathode, a thin layer of LiF or inorganic oxide, such as Li₂O can be disposed between the Al cathode and the Alq₃ ETL. This electrode structure has proved to be effective in lowering the work function. However, when the LiF coating is applied to a large area, a coating of uniform thickness may not be easy to achieve. Furthermore, LiF may affect the operational lifetime of the entire device.

It is thus desirable and advantageous to provide an electrode structure for use in an organic light-emitting device without the disadvantages of alkali fluorides and alkali oxides.

### SUMMARY OF THE INVENTION

The present invention provides an electrode structure for use on the cathode side of an organic light-emitting device. The electrode structure comprises at least a layer of noble or previous metal, such as Ag and Au, and a layer of Alq₃ doped with alkali fluoride or alkaline earth fluoride. The noble metal layer can be applied on the device by sputtering deposition. In order to minimize the physical impact of the coating material on the doped Alq₃ layer during the sputtering deposition process, a buffer layer of CuPc is provided on top of the doped Alq₃ layer. The work function of the noble metal is substantially equal to or greater than 4.2 eV.

Thus, the first aspect of the present invention provides a light emitting device, which comprises:

a hole source;

an organic emissive layer adjacent to the hole source;

an electron transport layer; and

an electrode structure comprising a buffer layer adjacent to the electron transport layer, and a cathode made from a noble metal, such as Ag, Au and Pt, wherein the buffer layer is made substantially from Alq₃ doped with at least a dopant selected from a group consisting of alkali fluoride and alkaline earth fluoride.

According to the present invention, the electrode structure further comprises a further buffer layer disposed between the cathode and the buffer layer, wherein the further buffer layer is made substantially of CuPc.

According to the present invention, the hole source comprises:

a hole transport layer adjacent to the organic emissive layer, an anode, and a hole injection layer disposed between the hole transport layer and the anode.

Alternatively, the light emitting device comprise:

a hole source;

an organic emissive layer adjacent to the hole source;

an electron transport layer made substantially of Alq₃:CsF/CuPc; and

an cathode made from a noble metal.

The second aspect of the present invention provides an electrode structure for use in an organic light emitting device, the organic light emitting device having:

a hole source;

an organic emissive layer adjacent to the hole source; and

an electron transport layer, said electrode structure comprising:

a buffer layer disposed adjacent to the electron transport layer; and

a cathode made from a noble metal, such as Ag, Au and Pt, wherein the buffer layer is made substantially from Alq₃ doped with at least a dopant selected from a group consisting of alkali fluoride and alkaline earth fluoride.

According to the present invention, the buffer layer is made substantially from Alq₃ doped with CsF.

According to the present invention, the electrode structure further comprises a further buffer layer made substantially from CuPc disposed between the buffer layer and the cathode.

The third aspect of the present invention provides a method of improving the efficiency in an organic light emitting device, the organic light emitting device comprising:

a substantially transparent substrate;

an anode disposed on the substrate;

a hole injection layer disposed on the anode;

a hole transport layer disposed on the hole injection layer;

an organic emitting layer disposed on the hole injection layer;

an electron transport layer disposed on the emitting layer, and

a cathode disposed adjacent to the transport layer, said method comprising:

selecting a metal having a work function substantially equal to or greater than 4.2 eV for use in the cathode; and

reducing the energy barrier between the cathode and the electron transport layer with a layer made substantially from Alq₃ doped with at least a dopant selected from a group consisting of alkali fluoride and alkaline earth fluoride.

The present invention will become apparent upon reading the description taken in conjunction with FIGS. 3 to 12.

### BRIEF DESCRIPTION OF THE DRAWINGS

FIG. 1 is a schematic representation showing a typical OLED.

FIG. 2 is a schematic representation showing an example of prior art OLED.

FIG. 3 is a schematic representation showing an OLED, according to one embodiment of the present invention.

FIG. 4 is a schematic representation showing an OLED, according to another embodiment of the present invention.

FIG. 5 is a plot of current density as a function of applied voltage.

FIG. 6 is a plot of luminance as a function of applied voltage.

FIG. 7 is a plot of current efficiency as a function of brightness.

FIG. 8 is a plot of current efficiency as a function of applied voltage.

FIG. 9 is a plot of 1931 CIE chromaticity in x coordinate as a function of applied voltage.

FIG. 10 is a plot of 1931 CIE chromaticity in y coordinate as a function of applied voltage.

FIG. 11 is a schematic representation showing a general structure of an OLED, according to the present invention.

FIG. 12 is a schematic representation showing yet another embodiment of the present invention.

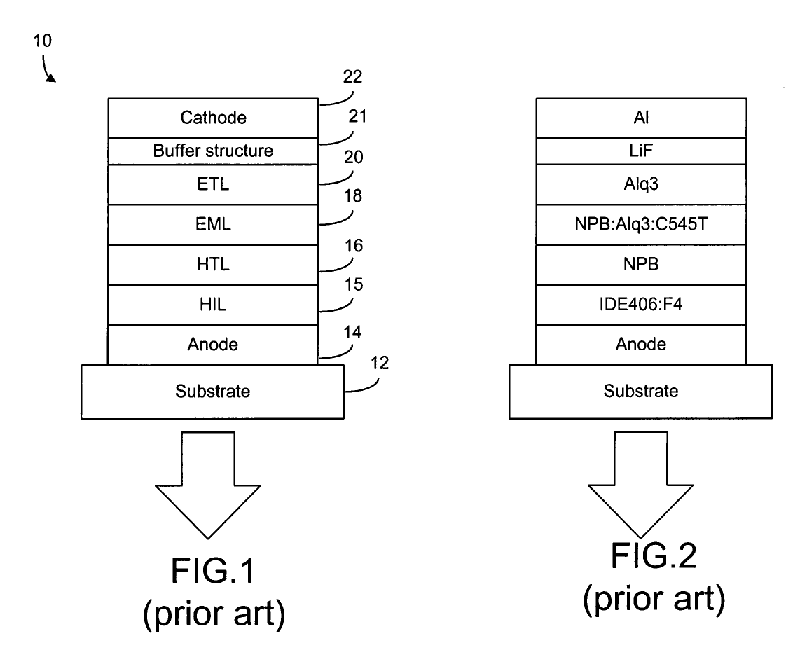

### DETAILED DESCRIPTION OF THE INVENTION

The present invention uses a layer of noble metal as the cathode for an organic light-emitting device. In particular, the work function of the noble metal is substantially equal to or greater than 4.2 eV. The major advantage of having a cathode made from a noble metal layer is that the cathode is less subject to oxidation and other corrosive conditions. In order to reduce the energy barrier between cathode and the electron transport layer which is made substantially from Alq₃ (LUMO=2.9 eV), a layer of Alq₃ doped with alkali fluoride or alkaline earth fluoride, such as CsF, is disposed between the electron transfer layer and the cathode.

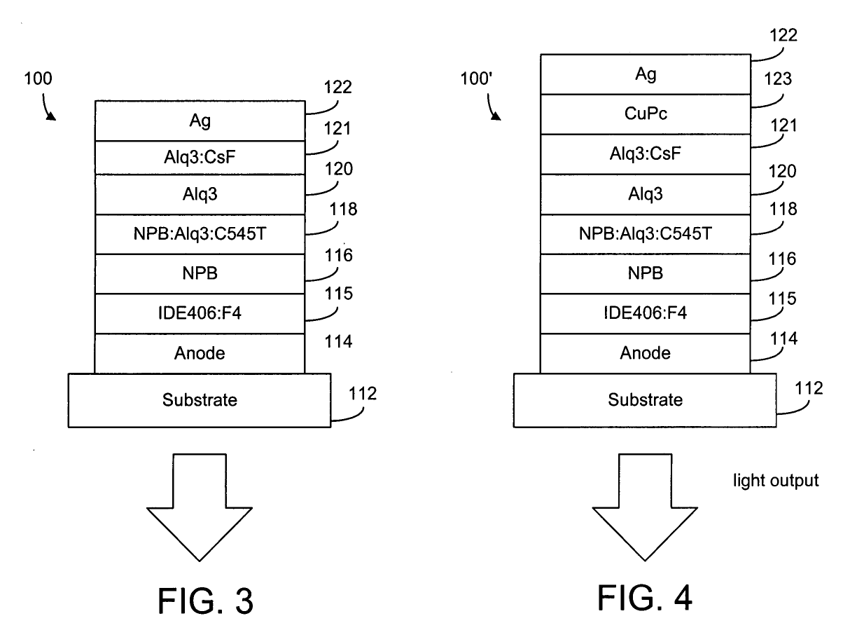

The OLED, according to one embodiment of the present invention, is shown in FIG. 3. As shown, the OLED 100 comprises:

an anode layer 114 disposed on a substantially transparent substrate 112,

a hole injection layer 115 disposed on the anode layer,

a hole transport layer 116,

an organic emissive layer 118,

an electron transport layer 120 made substantially from Alq₃,

a buffer layer 121 made substantially of Alq₃ doped with alkali fluoride, and

a cathode layer 122 made substantially of Ag.

The OLED, according to another embodiment of the present invention is shown in FIG. 4. As shown, the OLED 100′ is structurally similar to the OLED 100 as shown in FIG. 3, except for an additional buffer layer 123 disposed between the buffer layer 121 and the cathode layer 122. The additional buffer layer 123 can be made from CuPc.

Experiments

In order to compare the performance of the OLEDs, according to the present invention, against a prior art OLEDs, three experimental samples are made:

Sample I (prior art)

| Anode: | ITO | | |
|---|---|---|---|
| HIL: | IDE406:F4 | 60 | nm |
| HTL: | NPB | 20-30 | nm |
| EML: | NPB:Alq₃:C545T | 30-60 | nm |
| ETL: | Alq₃ | 30 | nm |
| Buffer layer: | LiF | 0.95 | nm |
| Cathode: | Al | 100 | nm |

Note: F4 is abbreviated for F4-TCNQ, which is a p-type dopant with a concentration of about 2% wt. NPB: Alq₃:C545T represents Alq₃ co-evaporated with NPB in 1:1 weight ratio to be a host and also mixed with C545T (1%) as a green dopant.

Sample II (first embodiment)

| Anode: | ITO | | |
|---|---|---|---|
| HIL: | IDE406:F4 | 60 | nm |
| HTL: | NPB | 20-30 | nm |
| EML: | NPB:Alq₃:C545T | 30-60 | nm |
| ETL: | Alq₃ | 10 | nm |
| Buffer layer: | Alq₃:CsF | 20 | nm |
| Cathode: | Ag | 100 | nm |

Sample III (second embodiment)

| Anode: | ITO | | |
|---|---|---|---|
| HIL: | IDE406:F4 | 60 | nm |
| HTL: | NPB | 20-30 | nm |
| EML: | NPB:Alq₃:C545T | 30-60 | nm |
| ETL: | Alq₃ | 10 | nm |
| Buffer 1: | Alq₃:CsF | 20 | nm |
| Buffer 2: | CuPc | 10 | nm |
| Cathode: | Ag | 100 | nm |

Experimental Results
A. Current Density J (mA/cm²)

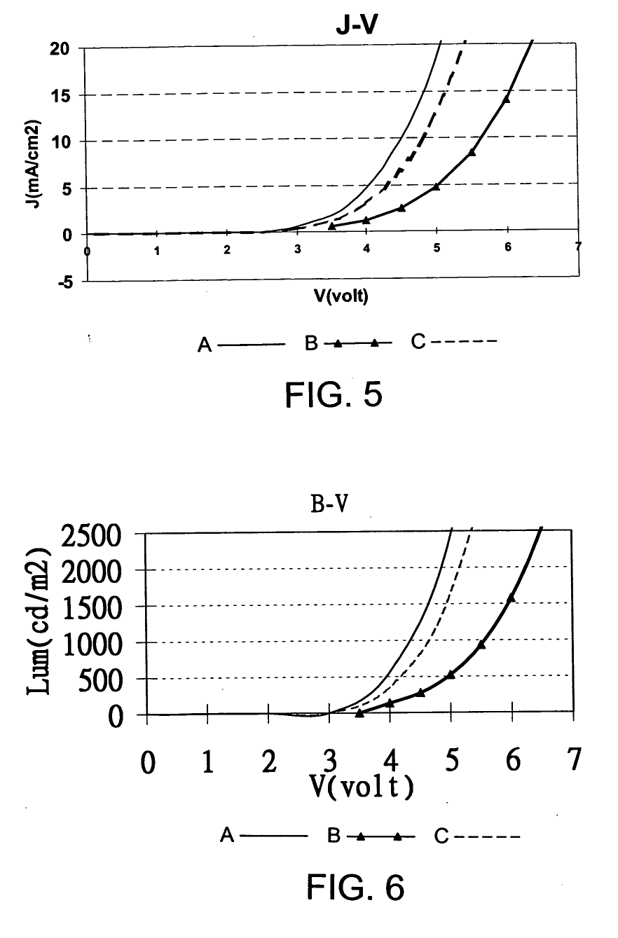

A plot of current density versus applied voltage is shown in FIG. 5. As can be seen in the plot, Samples II and III are more efficient than Sample I in terms of current density. In order to achieve the same current density, an approximately 20% higher applied voltage must be used in Sample I. For example, with J=14 mA/cm², V(Sample I)=6V; V(Sample III)=5.1V and V(Sample II)=4.8V.

B. Luminance (cd/m²)

A plot of luminance versus applied voltage is shown in FIG. 6. As can be seen in the plot, Samples II and III are more efficient than Sample I in terms of luminance. In order to achieve the same luminance, an approximately 20% higher applied voltage must be used in Sample I. For example, with Lum=1500 cd/m², V(Sample I)=6V; V(Sample III)=5.1V and V(Sample II)=4.6V.

C. Current Efficiency (cd/A)

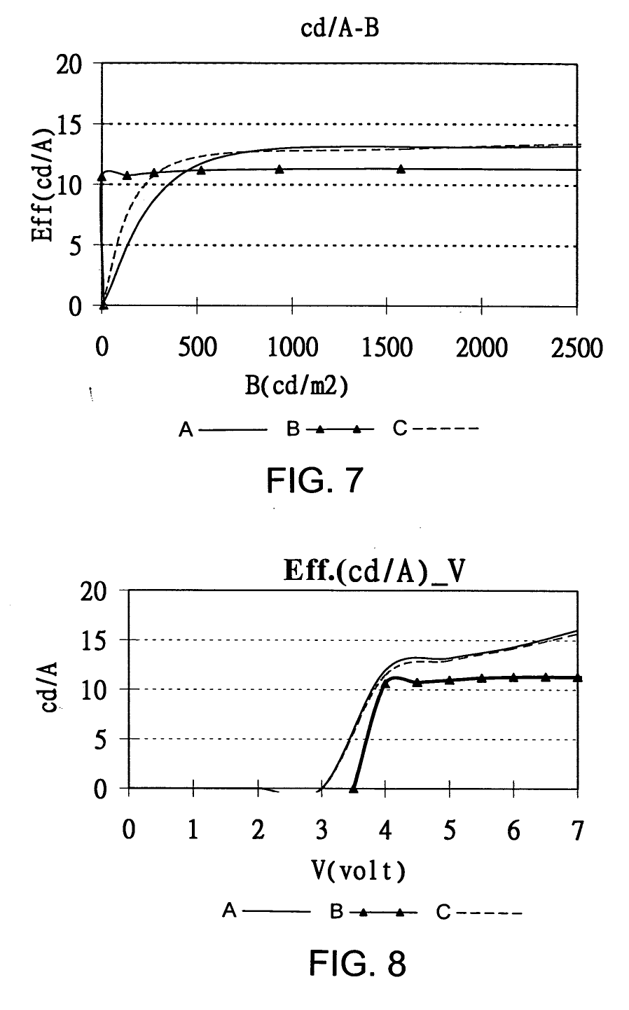

A plot of current efficiency versus brightness is shown in FIG. 7, and a plot of current efficiency versus voltage is shown in FIG. 8. As can be seen in the plots, Samples II and III are more current efficient than Sample I. Beyond the brightness of 1000 (nit=cd/m²), the current efficiency of Samples II and III is about 12% higher than that of Sample I. For example, with brightness=2000 (nits), Efficiency (Sample I)=11.8 (cd/A) @6.3V; Efficiency (Sample III)=13.5 (cd/A) @5.2V and Efficiency (Sample I)=13 (cd/A) @4.8V.

D. Chromaticity CIEₓ

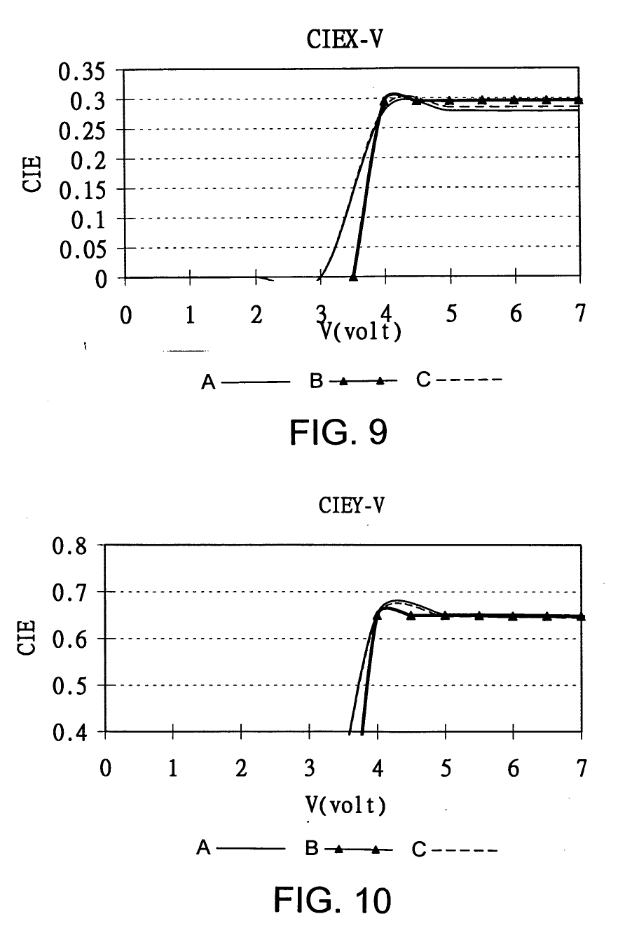

A plot of 1931 CIEₓ versus voltage is shown in FIG. 9. As can seen in the plot, 1931 CIEₓ for Samples II and III is slightly lower than that of Sample I. Beyond the applied voltage of 4V, CIEₓ(Sample 1)=0.29; CIEₓ (Samples II, III)=0.28.

E. Chromaticity CIE_{y}

A plot of 1931 CIE_{y} versus voltage is shown in FIG. 10. As can be seen in the plot, 1931 CIE_{y} for Samples II and III is almost identical to that of Sample I. Beyond the applied voltage of 4V, CIE_{y} (Sample I)=CIE_{y} (Samples II, III)=0.65.

### SUMMARY

The experimental results show that Sample II and Sample III, based on the two embodiments of the present invention, are more efficient than Sample I of a prior art OLED. The chromaticity of the OLEDs, according to the present invention, is approximately the same as that of the prior art OLED. However, because of the increase in electron injection, the diode is more power efficient. The overall performance of the OLED according to the present invention as compared to that of a prior art OLED is shown in TABLE I.

TABLE I

| | | Voltage | Current | Power | J(mA/cm2) | CIE 1931 |
|---|---|---|---|---|---|---|
| | Brightness(nits) | drop | eff.(cd/A) | eff.(lm/W) | @ 6 V | coordinate |
| Sample II | 2000 | ˜4.8 | ˜13 | ˜9 | 48 | ˜(0.28, 0.65) |
| Sample III | 2000 | ˜5.2 | ˜13.5 | ˜7.2 | 35 | ˜(0.28, 0.65) |
| Sample I | 2000 | ˜6.3 | ˜11.8 | ˜5.7 | 14 | ˜(0.29, 0.65) |

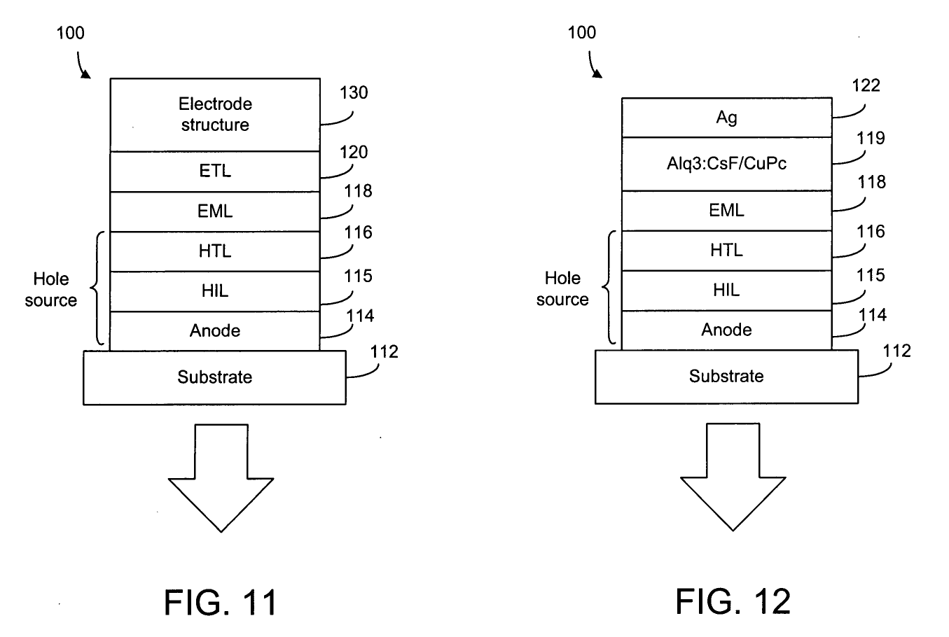

The present invention has been disclosed in reference to two embodiments as shown in FIGS. 3 and 4. It is understood for those skilled in the art that many variations can be made to those embodiments without changing the scope of the present invention. For example, the HTL 116 can be made from another one of aromatic tertiary amines, such as 2,6-Bis(di-p-tolylamine)naphthalene, instead of NPB. Likewise, the cathode can be made from Au and Pt, instead of Ag. Thus, the general structure of the OLED, according to the present invention, is shown in FIG. 11. As shown in FIG. 11, the OLED 100 comprises a hole source disposed on a substrate 112, an organic EML 118, an ETL 120 and an electrode structure 130 disposed on top of the ETL. The hole source comprises an anode 114 and an HTL 116. The hole source may additionally comprise an HIL 115. The electrode structure 130 comprises a cathode 122 and a buffer layer 121. The cathode 122 can be made from a noble or precious metal, such as Ag, Au and Pt, with a work function substantially equal to or greater than 4.2 eV. The buffer layer 121 is made substantially from Alq₃ doped with alkali fluoride or alkaline earth fluoride, such as CsF. Additionally, the electrode structure 130 comprises another buffer layer 123 disposed between the cathode 122 and the buffer layer 121. The additional buffer layer 123 is substantially made from CuPc, for example.

Furthermore, in the embodiment as shown in FIG. 4, the Alq₃ layer 120, the Alq₃:CsF layer 121 and the CuPc layer 123 effectively form an ETL 119. This Alq₃:CsF/CuPc ETL 119 can be directly disposed adjacent to the EML 118, without the Alq₃ layer 120, as shown in FIG. 12. Furthermore, the cathode 122, the buffer layer 121 and the Alq₃ layer 120 in FIG. 3 form an electron source for the EML 118 in that particular embodiment. Likewise, the cathode 122, the first buffer layer 121, the second buffer layer 123, and the Alq₃ layer 120 in FIG. 4 form the electron source in that different embodiment. Similarly, the electrode structure 130 and the ETL 120 in FIG. 11, and the cathode 122 and the Alq₃:CsF/CuPc layer 119 in FIG. 12 also form an electron source in each of those embodiments.

Thus, although the invention has been described with respect to one or more embodiments thereof, it will be understood by those skilled in the art that the foregoing and various other changes, omissions and deviations in the form and detail thereof may be made without departing from the scope of this invention.

What is claimed is:

1. A light emitting device, comprising:
a hole source;
an organic emissive layer adjacent to the hole source;
an electron transport layer; and
an electrode structure comprising a buffer layer adjacent to the electron transport layer, and a cathode made from at least one noble metal, wherein the buffer layer is made substantially from Alq₃ doped with at least a dopant selected from the group consisting of alkali fluoride and alkaline earth fluoride.

2. The light emitting device of claim 1, wherein the electrode structure further comprises a further buffer layer disposed between the cathode and the buffer layer, wherein the further buffer layer is made substantially from CuPc.

3. The light emitting device of claim 1, wherein the cathode is made substantially from Ag.

4. The light emitting device of claim 1, wherein the cathode is made substantially from one or more noble metals selected from the group consisting of Ag, Au and Pt.

5. The light emitting device of claim 1, wherein the buffer layer is made substantially from Alq₃ doped with CsF.

6. The light emitting device of claim 1, wherein the electron transport layer is made substantially from Alq₃.

7. The light emitting device of claim 5, wherein the electron transport layer is made substantially from Alq₃, and the cathode is made substantially from Ag.

8. The light emitting device of claim 1, wherein the hole source comprises:
a hole transport layer adjacent to the organic emissive layer; and
an anode.

9. The light emitting device of claim 8, wherein the hole source further comprises a hole injection layer disposed between the hole transport layer and the anode.

10. An electrode structure for use in an organic light emitting device, the organic light emitting device having:
a hole source;
an organic emissive layer adjacent to the hole source; and
an electron transport layer, said electrode structure comprising:
a buffer layer disposed adjacent to the electron transport layer; and
a cathode made from a noble metal, wherein the buffer layer is made substantially from Alq₃ doped with at least a dopant selected from the group consisting of alkali fluoride and alkaline earth fluoride.

11. The electrode structure of claim 10, wherein the cathode is made from one or more metals selected from the group consisting of Ag, Au and Pt.

12. The electrode structure of claim 10, wherein the cathode is made substantially from Ag and the buffer layer is made substantially from Alq₃ doped with CsF.

13. The electrode structure of claim 10, wherein the electrode structure further comprises a further buffer layer made substantially from CuPc disposed between the buffer layer and the cathode.

14. A method of improving the efficiency in an organic light emitting device, the organic light emitting device comprising:
a substantially transparent substrate;
an anode disposed on the substrate;
a hole injection layer disposed on the anode;
a hole transport layer disposed on the hole injection layer;
an organic emitting layer disposed on the hole injection layer;
an electron transport layer disposed on the emitting layer, and a cathode disposed adjacent to the transport layer, said method comprising the steps of:
selecting a metal having a work function substantially equal to or greater than 4.2 eV for use in the cathode; and
reducing the energy barrier between the cathode and the electron transport layer with a buffer layer made substantially from Alq₃ doped with at least a dopant selected from the group consisting of alkali fluoride and alkaline earth fluoride.

15. The method of claim 14, wherein the buffer layer is made substantially from Alq₃ doped with CsF.

16. The method of claim 14, further comprising the step of protecting the buffer layer with a layer substantially made of CuPc disposed between the buffer layer and the cathode.

17. A light emitting device, comprising:
an organic emissive layer having a first side and an opposing second side;
a hole source for providing holes to the organic emissive layer on the first side; and
an electron source for providing electrons to the organic emissive layer on the second side, wherein the electron source comprises:
a cathode made substantially from a noble metal, and
a layer structure disposed between the cathode and the organic emissive layer, the layer structure containing Alq₃ doped with a dopant selected from the group consisting of alkali fluoride and alkaline earth fluoride.

18. The light emitting device of claim 17, wherein the layer structure is made substantially of Alq₃:CsF/CuPc.

19. The light emitting device of claim 17, wherein the layer structure comprises
a layer made substantially from Alq₃ doped with CsF disposed adjacent to the cathode, and
a layer made substantially from Alq₃ disposed between the Alq₃:CsF layer and the organic emissive layer.

20. The light emitting device of claim 19, wherein the layer structure further comprises a layer made substantially from CuPc disposed between the cathode and the Alq₃:CsF layer.
